(19) United States
(12) Patent Application Publication
(10) Pub. No.: US 2009/0201115 A1
(43) Pub. Date: Aug. 13, 2009

(54) INDUCTANCE ELEMENT IN AN INTEGRATED CIRCUIT PACKAGE

(76) Inventors: Sajol Ghoshal, El Dorado Hills, CA (US); Philip John Crawley, Sacramento, CA (US)

Correspondence Address: KOESTNER BERTANI LLP, 2192 Martin St., Suite 150, Irvine, CA, 92612, US

(21) Appl. No.: 12/030,669

(22) Filed: Feb. 13, 2008

(51) Int. Cl. H01F 5/00; H01F 41/00

(52) U.S. Cl. 336/200; 29/602.1

(57) ABSTRACT

An electronic circuit in an integrated circuit package comprises an inductance element. The inductance element further comprises a plurality of separated metal strips formed on a substrate and a ferrite core coupled to the substrate. The metal strip plurality is formed between the substrate and the ferrite core. The inductance element further comprises a plurality of wires coupled to the separated metal strips whereby the metal strips and wires form a continuous coil. The ferrite core is interposed between the metal strip plurality and the wire plurality.

### BACKGROUND

Inductors and transformers are useful components in electronic circuits. Inductors are useful for construction of passive filters, voltage-controlled oscillators (VCOs), matching networks, transformers, and the like.

Transformers are devices that transfer electrical energy from one circuit to another through inductively coupled electrical conductors. A changing current in a primary circuit creates a changing magnetic field that induces a changing voltage in a secondary circuit. A load applied to the secondary circuit creates current flow in the transformer, thereby transferring energy between circuits.

### SUMMARY

According to an embodiment of an electronic circuit in an integrated circuit package comprises an inductance element. The inductance element further comprises a plurality of separated metal strips formed on a substrate and a ferrite core coupled to the substrate. The metal strip plurality is formed between the substrate and the ferrite core. The inductance element further comprises a plurality of wires coupled to the separated metal strips whereby the metal strips and wires form a continuous coil. The ferrite core is interposed between the metal strip plurality and the wire plurality.

### BRIEF DESCRIPTION OF THE DRAWINGS

Embodiments of the invention relating to both structure and method of operation may best be understood by referring to the following description and accompanying drawings:

FIGS. 1A through 1P are pictorial overhead views depicting embodiments of electronic circuits that include at least one inductance element; and

FIGS. 2A through 2C are flow charts showing one or more embodiments or aspects of a technique for manufacturing an integrated circuit.

### DETAILED DESCRIPTION

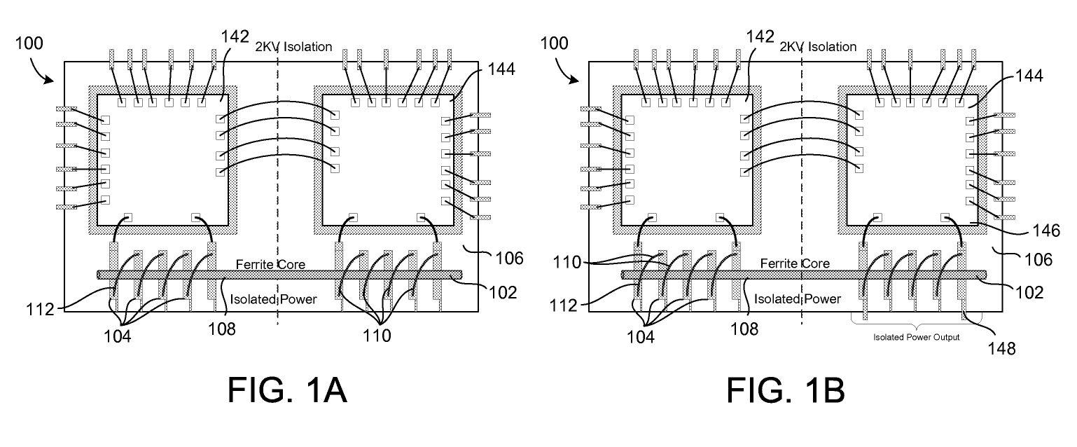

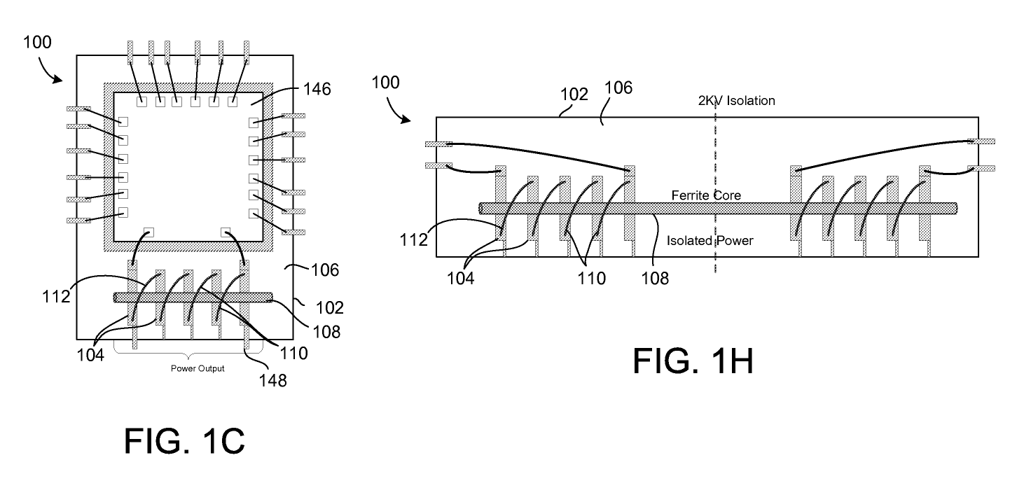

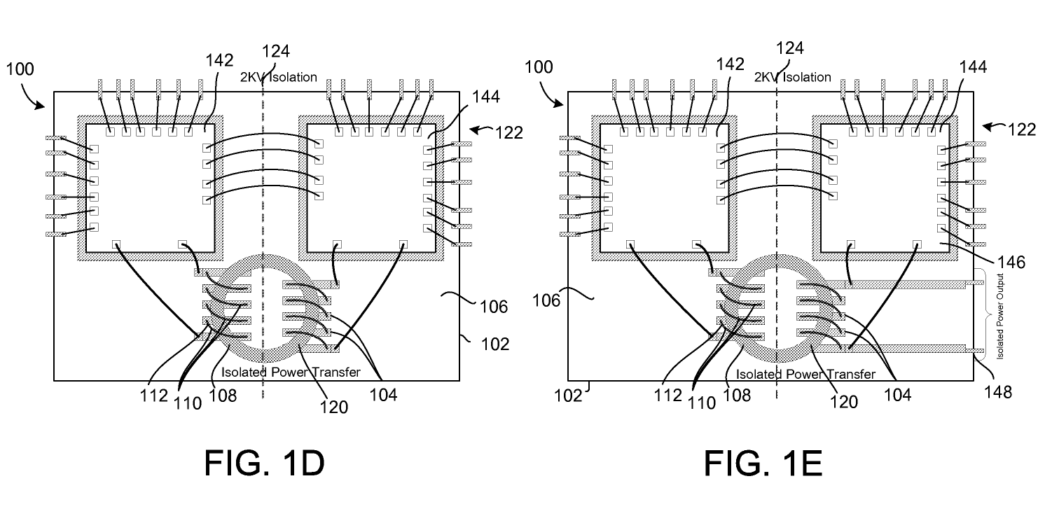

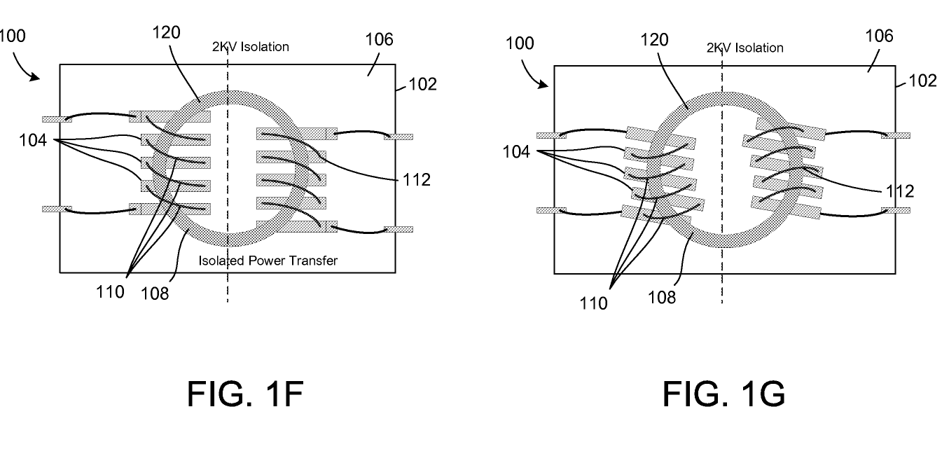

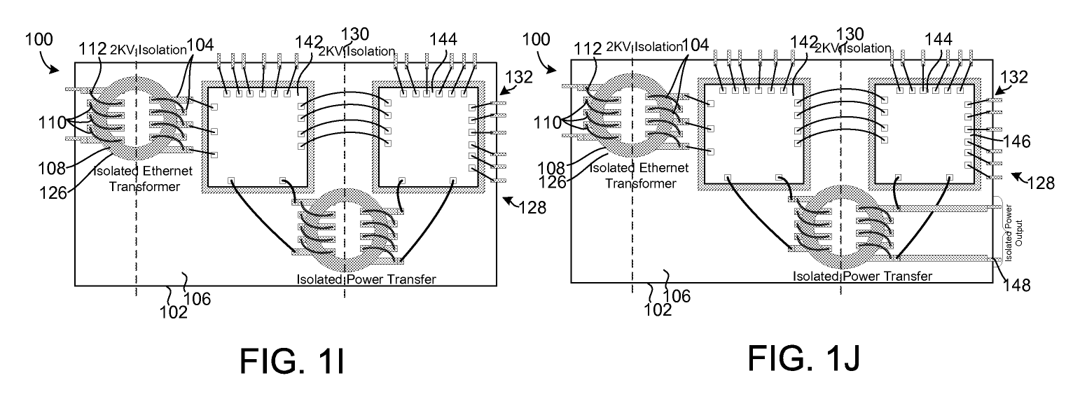

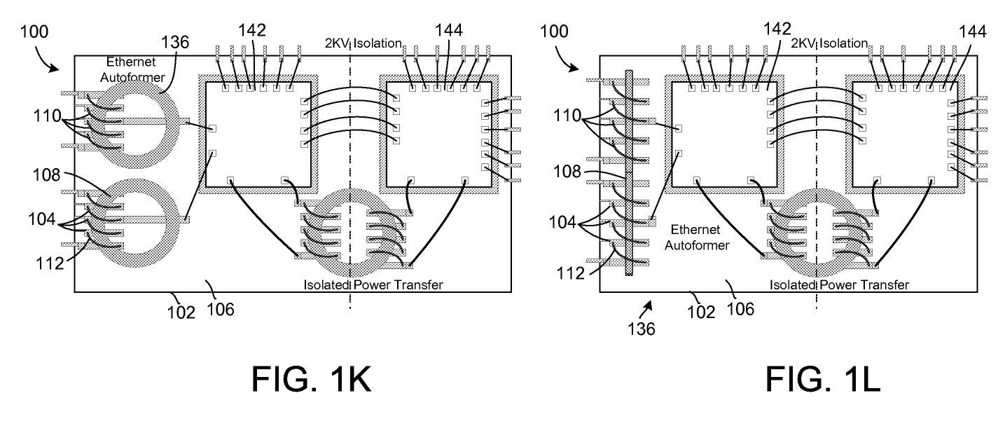

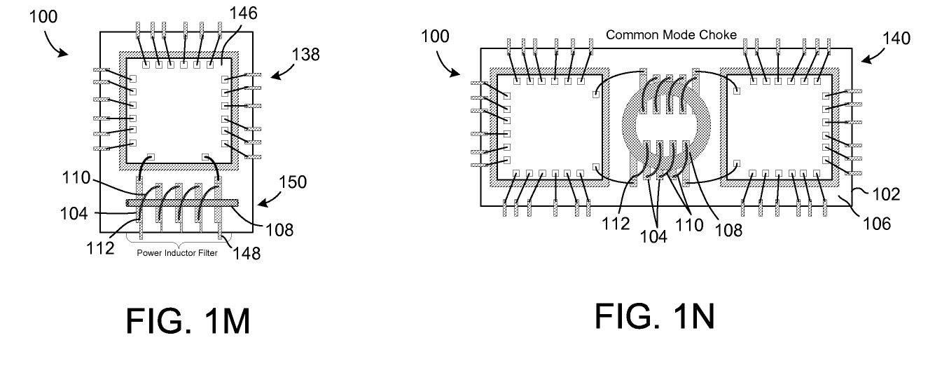

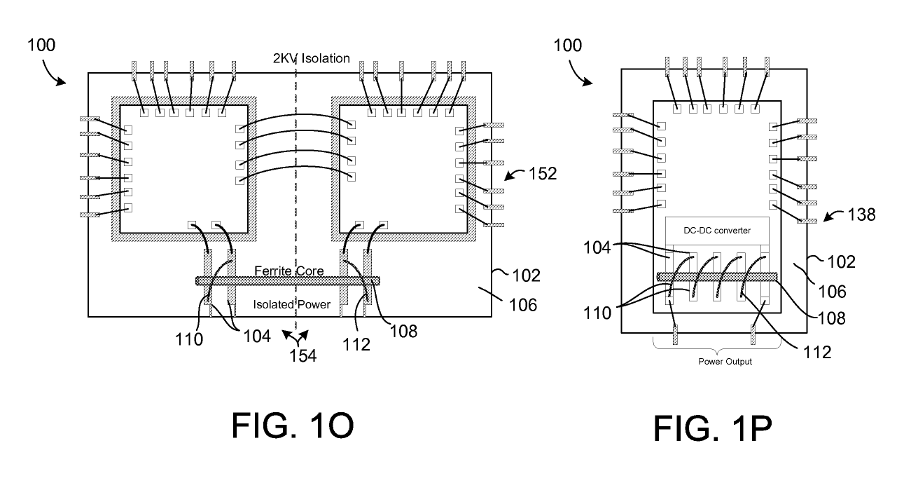

Referring to FIGS. 1A through 1N, several pictorial overhead views depict embodiments of electronic circuits that include at least one inductance element. Referring to FIG. 1A, an electronic circuit 100 in an integrated circuit package comprises an inductance element 102. The inductance element 102 further comprises multiple separated metal strips 104 formed on a substrate 106 and a ferrite core 108 coupled to the substrate 106. The metal strips 104 are formed between the substrate 106 and the ferrite core 108. The inductance element 102 further comprises multiple wires 110 coupled to the separated metal strips 104 whereby the metal strips 104 and wires 110 form a continuous coil 112. The ferrite core 108 is interposed between the metal strips 104 and the wires 110.

The wires 110 can be bond wires that connect around the ferrite core 108 from the separated metal strips 104 formed on the substrate. In an example implementation, the bond wires 110 can be connected to the metal strips 104 using a semiconductor device auto-bonding process.

An insulating material (not shown) is formed around the ferrite core 108. For example, the ferrite core 108 can be wrapped in an insulating tape or other insulating material.

Fundamental elements of the electronic circuit 100 include the ferrite core 108 which is located in the package. The package has metallization below the ferrite core 108 which forms the metal strips 104. In an example configuration, for a coil 112 that includes four turns around the ferrite 108 the metallization can include five metal strips 104 below the ferrite 108. A typical cross-section of the inductance element 102 can include metallization, insulation, ferrite 108, then additional insulation above the ferrite 108. Then bond wire 110 can be used to connect diagonally from one strip 104 across the ferrite 108 to conductively contact an adjacent metal strip.

In some applications and embodiments, the inductance element 102 can be configured to operate as an inductor.

The separated metal strips 104 can be arranged as mutually parallel-aligned strips with the wires 110 coupled diagonally across the ferrite core 108 so that the metal strips 104 and wires 110 form a continuous coil 112.

Any suitable type of ferrite core 108 can be used for the inductance element 102. Some embodiments, for example as shown in FIGS. 1A, 1B, 1C, 1H, 1L, and 1M, include a ferrite core or cores 108 in the form of a ferrite bar. Similarly, for example as shown in FIGS. 1D, 1E, 1F, 1G, 1I, 1J, 1K, 1L, and 1N, include a ferrite core or cores 108 in the form of a ferrite toroid.

Referring to FIGS. 1D, 1E, 1F, and 1G, an inductance element 102 can be configured as a power-switching transformer 120.

In an example application, a power-switching transformer can be completely integrated in a single package with power output at a sink.

As depicted in FIGS. 1D and 1E, the integrated circuit 100 can include a transformerless physical layer (PHY) 122 and the inductance element 102 can be coupled to the transformerless PHY 122 to function as a digital isolator 124 for the transformerless PHY 122.

Referring to FIGS. 1F, 1G, and 1H show example embodiments of an electronic device 100 comprising a semiconductor substrate 106, a ferrite core 108 formed on the substrate 106, and a coil 112 formed around the ferrite core 108. The coil 112 comprises multiple separated metal strips 104 on a first side of the ferrite core 108 and multiple bond wires 110 on a second side opposing the first side of the ferrite core 108. The metal strips 104 and bond wires 110 are coupled to form the coil.

The bond wires 110 connect around the ferrite core 108 from the separated metal strips 104 formed on the substrate 106 and can be connected to the metal strips 104 using a semiconductor device auto-bonding process.

Referring to FIGS. 11 and 1J, an inductance element 102 can be configured as a transformer 126. An integrated circuit 100 can comprise an Ethernet interface 128 with the inductance element 102 coupled to the Ethernet interface 128 comprising a digital isolator 130 for the Ethernet interface 128.

In an example implementation, an integrated circuit 100 can include an Ethernet physical layer (PHY) 132 and the inductance element 102 can function as a digital isolator 130 for the Ethernet PHY 132 whereby the Ethernet PHY 132 is split across the digital isolator 130.

The inductance element 102 can be implemented to attain several aspects of functionality. For example, the inductance element 102 can be used in an Ethernet interface that includes digital isolation. The Ethernet PHY can be split across the digital isolator. Implementations of the inductance element 102 can also be used to construct a transformerless PHY.

In various embodiments and applications, the number of turns of a coil 112 can be selected according to desired functionality. For example, a coil 112 can be constructed with four turns, five turns, or N turns. The size of the metal strips 104 and wires 110 can also be selected according to implementation or application. Typical sizes of the metal strips 104 are 2 millimeters or 4 millimeters in length, although any suitable length can be implemented. For example, a configuration of metal strips of 4 millimeters (mm) in length coupled by bond wires 110 can form a coil 112 on one side of a ferrite toroid 108 and a similar coil 112 can be formed on a second side of the ferrite toroid 108, for example to form a transformer 126 which can be coupled to the PHY 132.

The inductance element can be formed using a ferrite bar, however electromagnetic interference (EMI) can leak from the ends of the bar. Thus, a ferrite toroid can be used, which reduces EMI because the toroid is closed, avoiding EMI leakage.

For a configuration in which each turn of the bond wire 110 has an inductance of approximately 1-2 nanoHenry (nH). With addition of the toroid, inductance is substantially increased. For a configuration with inductance of 1-2 μH per turn and a coil with 5 or 6 turns, then a total inductance of 20 to 50 μH can be attained.

Referring to FIGS. 1K and 1L, the inductance element 102 can be configured as an auto-former 136.

The auto-former 136 configuration can be implemented for Ethernet applications for accessing a power-over-Ethernet PoE signal with digital isolation. The auto-former 136 includes transformer across the winding with a center tap that is accessed to pull power. The illustrative structures and associated manufacturing techniques enable the auto-former 136 to be constructed inside a package.

Referring to FIG. 1M, an integrated circuit 100 can include a DC-DC converter 138 and the inductance element 102 can be coupled into the DC-DC converter 138 and function as an inductor.

The inductor 102 is shown in usage with the DC-DC converter 138 so that the inductor which is conventionally coupled outside an integrated circuit package can be moved inside the chip.

The integrated circuit 100 can comprise a an integrated circuit 146 coupled to the substrate 106, a power output terminal 148 of the integrated circuit package, and the inductance element 102 coupled between the integrated circuit 146 and the power output terminal 148 as a power inductor filter 150.

A further application of the illustrative inductance element structures is a filter for the inductor. Power supplies have inductors on the front end that connect to the power supply to ensure better supply fidelity. The illustrative structures and techniques enable front-end filtering on the power supply inside the package.

Referring to FIG. 1N, the inductance element 102 can be configured as a choke 140, for example a steering common-mode choke 140.

The inductance element application including on the choke 140 can be used for various purposes such as electromagnetic interference (EM I) suppression. The choke 140 can be used in EMI circuits including a differential design and a shunt design wherein EMI is shunted to ground, for example at half an ohm. The illustrative structure can be used to form a common mode choke that is steering. The steering common mode choke 140 can be constructed inside an integrated circuit package in addition to a shunt, enabling formation of both a choke and shunt.

In various embodiments, for example as shown in FIGS. 1A, 1B, 1D, 1E, 1I, 1J, 1K, and 1L, the integrated circuit 100 can comprise a first integrated circuit 142 coupled to the substrate 106, a second integrated circuit 144 coupled to the substrate 106, and the inductance element 102 coupled between the first and second integrated circuits as a digital isolator.

In various embodiments, for example as shown in FIGS. 1B, 1C, 1E, and 1J, the integrated circuit 100 can comprise a an integrated circuit 146 coupled to the substrate 106, a power output terminal 148 of the integrated circuit package, and the inductance element 102 coupled between the integrated circuit 146 and the power output terminal 148 as a power output isolator.

As shown in FIGS. 1D, 1E, 1F, 1G, 1I, 1J, 1K, and 1L, the inductance element 102 can be configured for power transfer, enabling a substantially higher power transfer than typically-used power transfer components such as capacitors. For example, a capacitor enables power transfer of on the order of 15 milliwatts and substantially higher performance is sought for various applications, for example on the order of 200-300 milliwatts. The illustrative ferrite coupling can attain power transfer performance of 200-300 milliwatts or higher, even up to 2-3 watts or even 6, 7 or 10 watts. For example, the configurations shown in FIGS. 1A through 1N can enable construction of an integrated circuit chip with an entire power conversion circuit contained within the chip. For example, a transformer inside a chip can have characteristics of low power and 7-10 watt power transfer.

FIG. 10 shows a package that incorporates a single-turn transformer 152 on two separate paddles 154.

Referring to FIG. 1P, a DC-DC converter 138 is shown which includes embedded inductors 108 added directly on the silicon substrate, with or without isolation, and not specifically on a separate substrate.

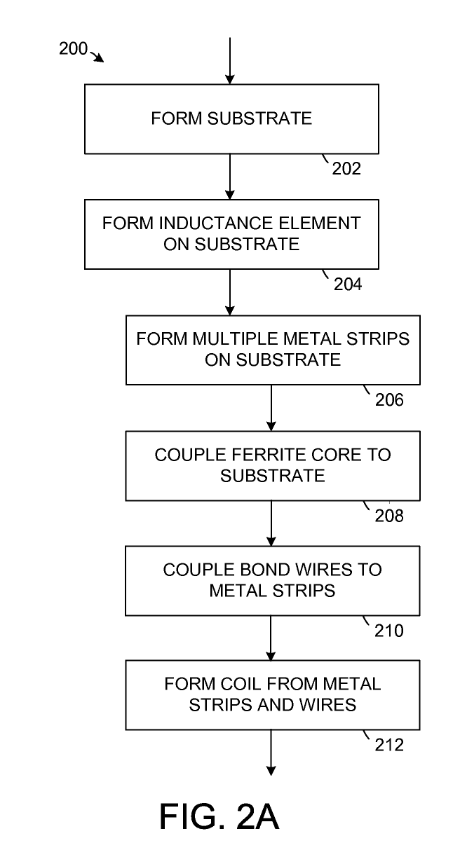

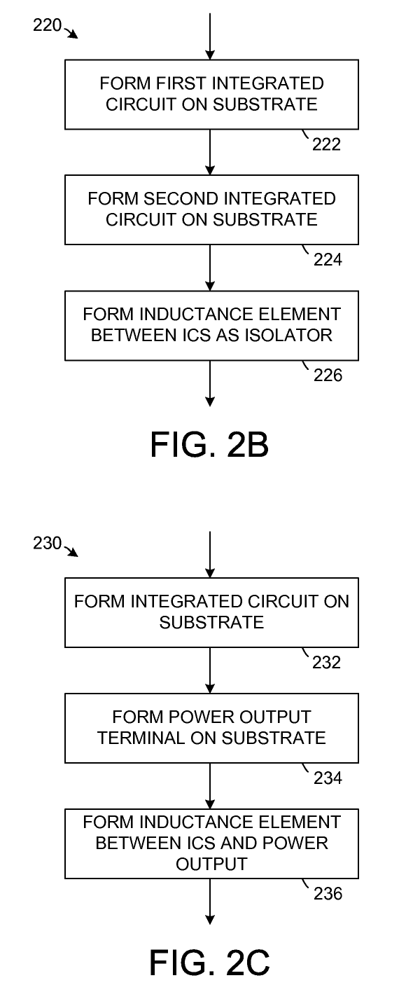

FIGS. 2A through 2C are flow charts showing one or more embodiments or aspects of a technique for manufacturing an integrated circuit. The illustrative technique enables construction or manufacture of an inductor, transformer, choke, or the like inside an electronics package. The technique further enables functional components to be constructed inside the electronics package that are generally formed outside a package.

Referring to FIG. 2A, a flow chart illustrates an embodiment of a method for manufacturing 200 an electronic circuit comprising forming 202 a substrate and forming 204 an inductance element on the substrate. The inductance element can be constructed by forming 206 a plurality of separated metal strips on the substrate and coupling 208 a ferrite core to the substrate. The metal strips are formed 206 between the substrate and the ferrite core. The inductance element is further constructed by coupling 210 a plurality of wires to the separated metal strips. The metal strips and wires are formed 212 into a continuous coil whereby the ferrite core is interposed between the metal strips and the wires.

The bond wires can be coupled 210 to the separated metal strips using a semiconductor device auto-bonding process.

Referring to FIG. 2B, another embodiment of a method for manufacturing 220 an electronic circuit can comprise forming 222 a first integrated circuit on the substrate and forming 224 a second integrated circuit on the substrate. An inductance element can be formed 226 between the first and second integrated circuits as a digital isolator.

Referring to FIG. 2C, another embodiment of a method for manufacturing 230 an electronic circuit can comprise forming 232 an integrated circuit on the substrate and forming 234 a power output terminal on an integrated circuit package. An inductance element can be formed 236 between the integrated circuit and the power output terminal as a power output isolator.

Terms “substantially”, “essentially”, or “approximately”, that may be used herein, relate to an industry-accepted tolerance to the corresponding term. Such an industry-accepted tolerance ranges from less than one percent to twenty percent and corresponds to, but is not limited to, component values, integrated circuit process variations, temperature variations, rise and fall times, and/or thermal noise. The term “coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. Inferred coupling, for example where one element is coupled to another element by inference, includes direct and indirect coupling between two elements in the same manner as “coupled”.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims. For example, various aspects or portions of a network interface are described including several optional implementations for particular portions. Any suitable combination or permutation of the disclosed designs may be implemented.

1. An electronic circuit in an integrated circuit package comprising:
an inductance element comprising:
a plurality of separated metal strips formed on a substrate;
a ferrite core coupled to the substrate, the metal strip plurality formed between the substrate and the ferrite core; and
a plurality of wires coupled to the separated metal strips whereby the metal strips and wires form a continuous coil, the ferrite core interposed between the metal strip plurality and the wire plurality.

2. The circuit according to claim 1 further comprising:
the plurality of wires comprising bond wires that connect around the ferrite core from the plurality of separated metal strips formed on the substrate.

3. The circuit according to claim 2 further comprising:
the bond wires are connected to the metal strips using a semiconductor device auto-bonding process.

4. The circuit according to claim 1 further comprising:
an insulating material formed around the ferrite core.

5. The circuit according to claim 1 further comprising:
the inductance element comprising an inductor.

6. The circuit according to claim 1 further comprising:
the inductance element comprising a transformer.

7. The circuit according to claim 1 further comprising:
the inductance element comprising a choke.

8. The circuit according to claim 1 further comprising:
the inductance element comprising an auto-former.

9. The circuit according to claim 1 further comprising:
the inductance element comprising a power-switching transformer.

10. The circuit according to claim 1 further comprising:
the plurality of separated metal strips comprise mutually parallel-aligned strips; and
the plurality of wires coupled diagonally across the ferrite core whereby the metal strips and wires form a continuous coil.

11. The circuit according to claim 1 further comprising:
the ferrite core comprising a ferrite bar.

12. The circuit according to claim 1 further comprising:
the ferrite core comprising a ferrite toroid.

13. The circuit according to claim 1 further comprising:
an Ethernet interface; and
the inductance element coupled to the Ethernet interface comprising digital isolator for the Ethernet interface.

14. The circuit according to claim 1 further comprising:
an Ethernet physical layer (PHY); and
the inductance element comprising digital isolator for the Ethernet PHY whereby the Ethernet PHY is split across the digital isolator.

15. The circuit according to claim 1 further comprising:
a transformerless physical layer (PHY); and
the inductance element coupled to the transformerless PHY comprising digital isolator for the transformerless PHY.

16. The circuit according to claim 1 further comprising:
a DC-DC converter; and
the inductance element coupled into the DC-DC converter comprising an inductor.

17. The circuit according to claim 1 further comprising:
a first integrated circuit coupled to the substrate;
a second integrated circuit coupled to the substrate; and
the inductance element coupled between the first and second integrated circuits as a digital isolator.

18. The circuit according to claim 1 further comprising:
an integrated circuit coupled to the substrate;
a power output terminal of the integrated circuit package; and
the inductance element coupled between the integrated circuit and the power output terminal as a power output isolator.

19. The circuit according to claim 1 further comprising:
an integrated circuit coupled to the substrate;
a power output terminal of the integrated circuit package; and
the inductance element coupled between the integrated circuit and the power output terminal as a power inductor filter.

20. An electronic device comprising:
a semiconductor substrate;
a ferrite core formed on the substrate; and
a coil formed around the ferrite core, the coil comprising a plurality of separated metal strips on a first side of the ferrite core and a plurality of bond wires on a second side opposing the first side of the ferrite core, the metal strips and bond wires coupled into the coil.

21. The electronic device according to claim 20 further comprising:
the bond wires connecting around the ferrite core from the plurality of separated metal strips formed on the substrate, the bond wires are connected to the metal strips using a semiconductor device auto-bonding process.

22. A method for manufacturing an electronic circuit comprising:
forming a substrate;
forming an inductance element on the substrate comprising:
forming a plurality of separated metal strips on the substrate;
coupling a ferrite core to the substrate, the metal strip plurality formed between the substrate and the ferrite core; and
coupling a plurality of wires to the separated metal strips; and
forming the metal strips and wires into a continuous coil whereby the ferrite core is interposed between the metal strip plurality and the wire plurality.

23. The method according to claim 22 further comprising:
coupling a plurality of bond wires to the separated metal strips using a semiconductor device auto-bonding process.

24. The method according to claim 22 further comprising:
forming a first integrated circuit on the substrate;
forming a second integrated circuit on the substrate; and
forming the inductance element between the first and second integrated circuits as a digital isolator.

25. The method according to claim 22 further comprising:
forming an integrated circuit on the substrate;
forming a power output terminal on an integrated circuit package; and
forming the inductance element between the integrated circuit and the power output terminal as a power output isolator.
